(19) United States
(12) Patent Application Publication
(10) Pub. No.: US 2025/0379153 A1
(43) Pub. Date: Dec. 11, 2025

(54) THROUGH-DEVICE LAYER VIAS WITH BACK SIDE FILL REPLACEMENT

(71) Applicant: Intel Corporation, Santa Clara, CA (US)

(72) Inventors: Abhishek A. Sharma, Portland, OR (US); Wilfred Gomes, Portland, OR (US)

(73) Assignee: Intel Corporation, Santa Clara, CA (US)

(21) Appl. No.: 18/734,447

(22) Filed: Jun. 5, 2024

(51) Int. Cl. H01L 23/535; H01L 21/8238; H01L 23/522; H01L 27/092; H01L 29/06; H01L 29/423; H01L 29/66; H01L 29/775; H01L 29/786

(52) U.S. Cl. CPC H01L 23/535; H01L 23/5226; H10D 30/014; H10D 30/031; H10D 30/43; H10D 30/6735; H10D 30/6757; H10D 62/121; H10D 84/0186; H10D 84/038; H10D 84/85

(57) ABSTRACT

An integrated circuit device includes a first metallization layer, a second metallization layer, and a transistor layer between the first and second metallization layers. The transistor layer includes a first gate structure, a second gate structure, and a conductive structure between the first and second gate structures. The conductive structure includes a first end having a first width, the first end closer to the first metallization layer than the second metallization layer. The conductive structure also includes a second end having a second width, the second end closer to the second metallization layer than the first metallization layer, the second width greater than the first width. A seam extends from the first end of the conductive structure partway towards the second end of the conductive structure.

### BACKGROUND

An integrated circuit (IC) device typically utilizes conductive interconnect layers to connect components in the IC device (such as transistors, e.g., in a transistor layer of the device) and/or to send and/or receive power and/or data signals external to the IC device. Common types of interconnect layers include copper and copper alloy interconnect lines coupled to individual components in the IC device and/or to other interconnect lines in the IC device by interconnect through vias in the IC device. In some IC designs, interconnect layers may be formed on both sides of the transistors, e.g., on a front side and a back side. For example, in some devices, gate, source, and/or drain contacts may be moved to the back side of the device. In some devices, power and/or signal connections may be formed on a back side of the device and extend through the transistor layer to the front side.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIGS. 1A and 1B are schematic illustrations of cross-sectional views of an example transistor, according to some embodiments of the present disclosure.

FIG. 2 is a cross-section of an IC device including a transistor layer between front and back side metallization layers, the transistor layer including through-device layer vias having back side fill replacements, according to some embodiments of the present disclosure.

FIG. 3 is a zoomed in view of a portion of the transistor layer shown in FIG. 2.

FIG. 4 is a flow diagram of an example process for manufacturing an IC device having a through-device layer via having a back side fill replacement, according to some embodiments of the present disclosure.

FIGS. 5A-5I are side, cross-sectional views of various stages of the example process of FIG. 4, according to some embodiments of the present disclosure.

FIGS. 6A and 6B are top views of a wafer and dies that include one or more IC devices with a through-device layer via having a back side fill replacement, in accordance with any of the embodiments disclosed herein.

FIG. 7 is a cross-sectional side view of an IC device that includes one or more IC devices with a through-device layer via having a back side fill replacement, in accordance with any of the embodiments disclosed herein.

FIG. 8 is a cross-sectional side view of an IC device assembly that includes one or more IC devices with a through-device layer via having a back side fill replacement, in accordance with any of the embodiments disclosed herein.

FIG. 9 is a block diagram of an example computing device that includes one or more IC devices with a through-device layer via having a back side fill replacement, in accordance with any of the embodiments disclosed herein.

### DETAILED DESCRIPTION

The systems, methods, and devices of this disclosure each have several innovative aspects, no single one of which is solely responsible for all of the desirable attributes disclosed herein. Details of one or more implementations of the subject matter described in this specification are set forth in the description below and the accompanying drawings.

IC devices typically include a metallization stack, which is a collection of several metal layers, stacked above one another, in which different interconnects are provided. As noted above, in some device architectures, both front side interconnect layers and back side interconnect layers, also referred to as front side metallization and back side metallization, are included. The front and back side metallization are provided on opposite sides of the transistor layer. Interconnect layers, also referred to as metal layers, include electrically conductive trenches, also referred to as lines, which provide connectivity across the layer, and electrically conductive vias (or, simply, “vias”) that provide electrical connectivity between different layers. In general, the term “trench” or “line” may be used to describe an electrically conductive element isolated by an insulator material (e.g., an insulator material typically comprising a low-k dielectric) that is provided in a plane parallel to the plane of an IC die/chip or a support structure over which an IC structure is provided, while the term “via” may be used to describe an electrically conductive element that interconnects two or more trenches of different levels of a metallization stack, or a component of the transistor layer and one or more trenches of a metallization layer. Together, trenches and vias may be referred to as “interconnects,” where the term “interconnect” may be used to describe any element formed of an electrically conductive material for providing electrical connectivity to/from one or more components associated with an IC or/and between various such components.

As interconnect layers are manufactured with lines and vias having smaller sizes and pitches in order to accommodate smaller IC devices, it becomes increasingly difficult to properly align vias with lines in a given interconnect layer. For example, during manufacturing of an IC device, the edges of a via may be misaligned with a trench to limitations or variations in manufacturing processes used to manufacture the IC device (e.g., limits to precision of photolithography processes used, variations in geometry of substrates on or in which the IC device is built, and so on). Misalignment can be increased as a result of bow, warp, or distortion in shapes of IC device interconnect layers or components due to heating or cooling during manufacturing processes (e.g., due to differences in thermal expansion between layers or components). If a via is misaligned and contacts a wrong interconnect feature in an IC device, the IC device may short circuit in use, resulting in degraded electrical performance. One solution to address this issue is to reduce sizes of vias used in the IC device, for example, by making the vias narrower. However, reduction of via sizes results in an increase in resistance and reduces yield during manufacturing.

Disclosed herein are IC devices and methods of manufacturing IC devices. An example IC device can include a first metallization layer (e.g., a front side metallization layer), a second metallization layer (e.g., a back side metallization layer), and a transistor layer between the first metallization layer and the second metallization layer. The transistor layer can include a first gate structure, a second gate structure, and a conductive structure (such as a via) between the first and second gate structures. The conductive structure can include a first end having a first width, the first end closer to the first metallization layer than the second metallization layer. The conductive structure can also include a second end having a second width, the second end closer to the second metallization layer than the first metallization layer, the second width greater than the first width. In some embodiments, a seam extends from the narrower first end of the conductive structure partway towards the wider second end of the conductive structure. In some embodiments, the conductive structure includes a material that forms crystals (e.g., a crystalline metal), and a grain size of the material is smaller near the wider end of the conductive structure than near the narrower end of the conductive structure.

The example IC device may be a product of a method of manufacturing an IC device in which an IC assembly including a transistor layer is provided, and dummy vias including a dummy via fill are formed in the transistor layer (e.g., through dielectric material between gate structures of transistors in the transistor layer). Front side metallization layers may be formed over a front side of the transistor layer, and the IC assembly may be flipped or turned over to expose the back side of the transistor layer. The dummy vias are etched to form cavities. Optionally, the cavities are partially filled with a via liner. The cavities are filled with a conductive via fill material. Back side metallization layers can be formed over the back side of the IC assembly. Advantageously, the dummy via fill material of the dummy vias may have a lower coefficient of thermal expansion than the conductive via fill material, or the dummy via fill material may have other characteristics or properties that help to minimize potential misalignment issues that may arise during IC device manufacturing processes (e.g., due to bow, warp, or distortion in an IC device that might be encountered due to heating or cooling of the IC device during formation of front side metallization layers, for example). IC devices described herein may have improved alignment between vias (e.g., vias in a transistor layer) and lines (e.g., interfacing with the vias in the transistor layer), allowing for improved electrical performance.

In the following, some descriptions may refer to a particular source or drain region or contact being either a source region/contact or a drain region/contact. However, unless specified otherwise, which region/contact of a transistor is considered to be a source region/contact and which region/contact is considered to be a drain region/contact is not important because, as is common in the field of transistors, designations of source and drain are often interchangeable. Therefore, descriptions of some illustrative embodiments of the source and drain regions/contacts provided herein are applicable to embodiments where the designation of source and drain regions/contacts may be reversed.

As used herein, the term “metallization layer” may refer to a layer on a side of a support structure that includes electrically conductive interconnect structures for providing electrical connectivity between different IC components. Metallization layers described herein may also be referred to as “interconnect layers” to clearly indicate that these layers include electrically conductive interconnect structures which may include but do not have to include metal.

In the following detailed description, various aspects of the illustrative implementations may be described using terms commonly employed by those skilled in the art to convey the substance of their work to others skilled in the art. For example, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. As used herein, a “logic state” (or, alternatively, a “state” or a “bit” value) of a memory cell may refer to one of a finite number of states that the cell can have, e.g., logic states “1” and “0,” each state represented by a different voltage of the capacitor of the cell, while “READ” and “WRITE” memory access or operations refer to, respectively, determining/sensing a logic state of a memory cell and programming/setting a logic state of a memory cell. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−20% of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

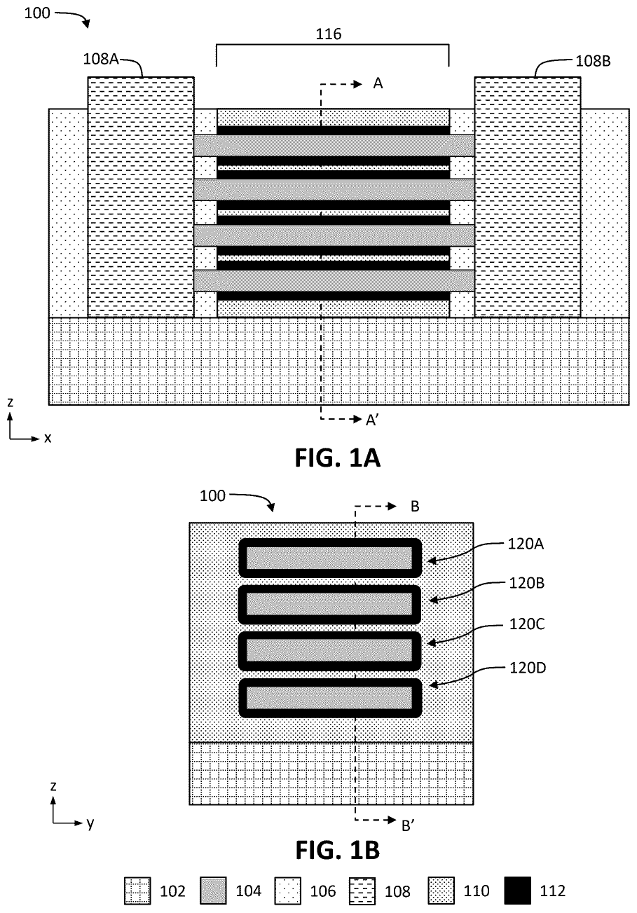

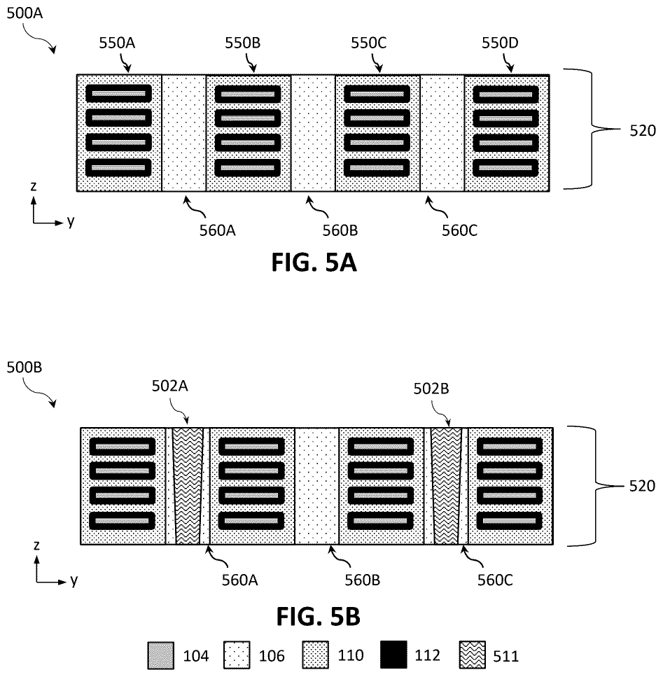

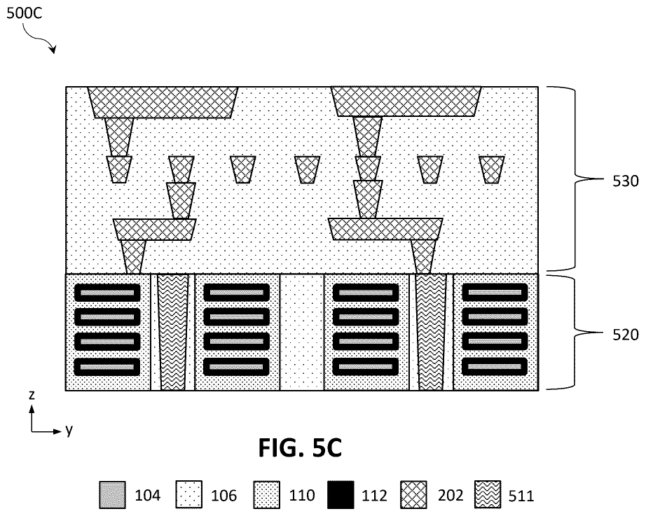

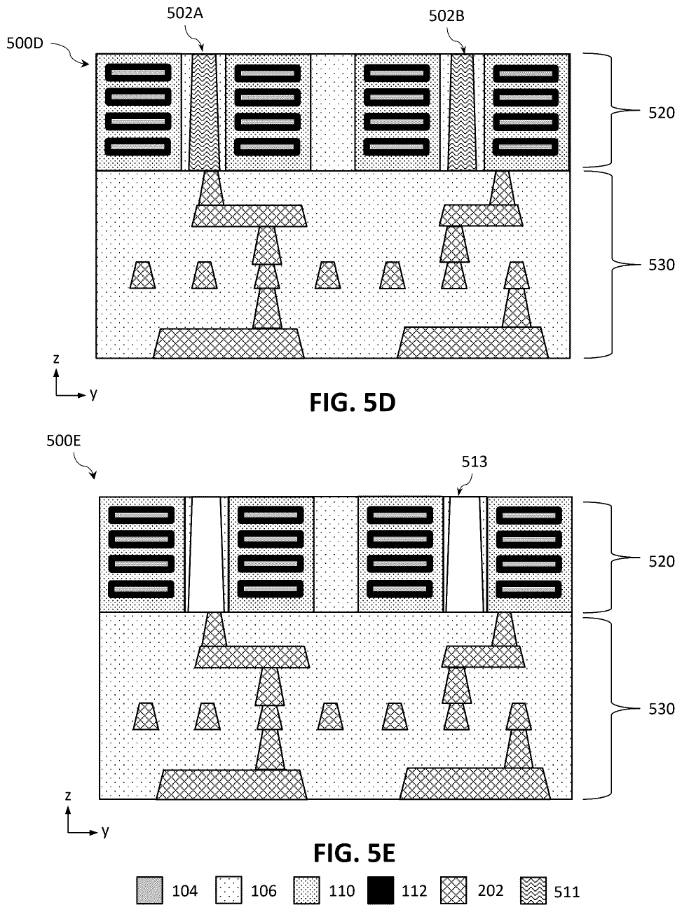

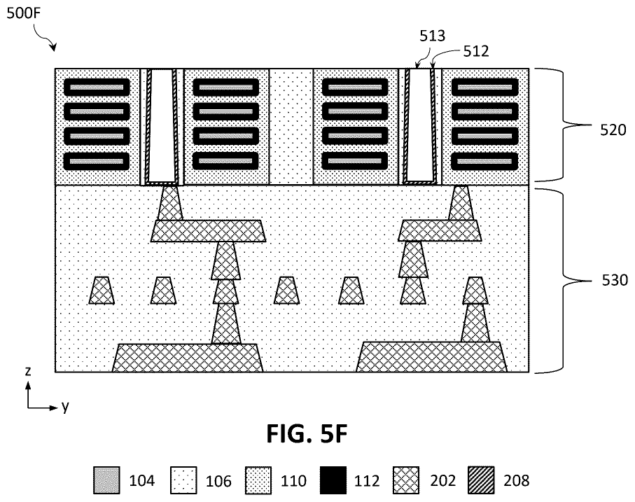

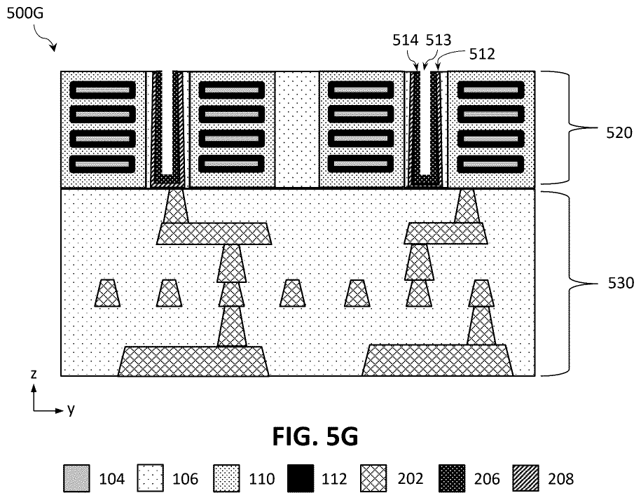

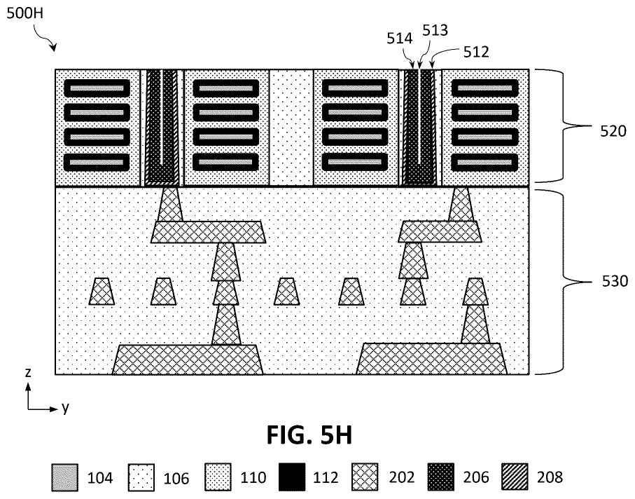

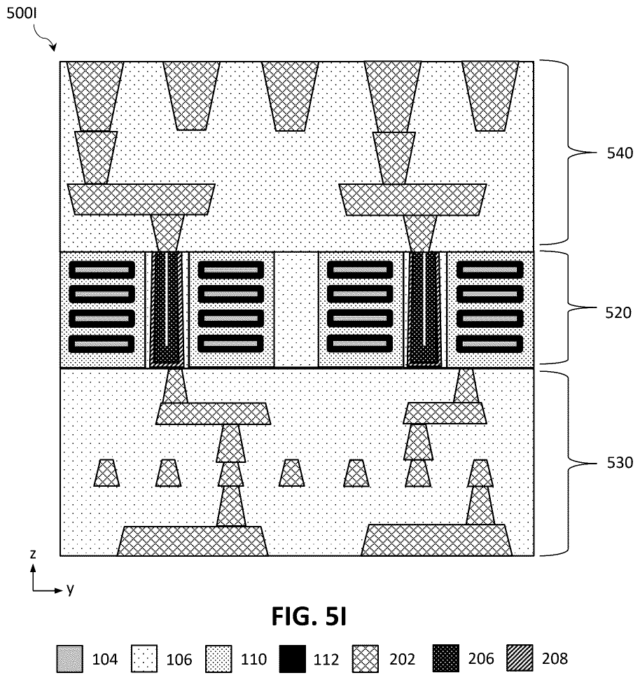

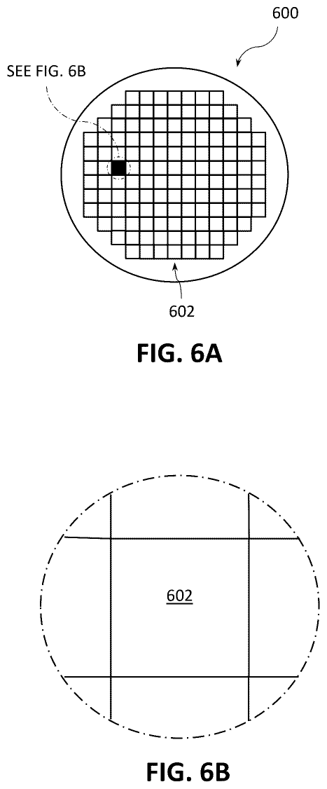

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense. For convenience, the phrase “FIG. 1” may be used to refer to the collection of drawings of FIGS. 1A-1B, the phrase “FIG. 5” may be used to refer to the collection of drawings of FIGS. 5A-5I, the phrase “FIG. 6” may be used to refer to the collection of drawings of FIGS. 6A-6B, etc.

In the drawings, some example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects or features could also be visible, e.g., not-perfectly straight edges of materials, tapered vias or other openings, rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Various IC devices as described herein (e.g., having through-device layer vias having back side fill replacements) may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

FIGS. 1A-1B illustrate an example architecture of a nanoribbon-based transistor. FIG. 1A is a cross-section across a transistor 100 showing a channel, a source, a gate region, and a drain. FIG. 1B is a cross-section across the gate region of the transistor 100. FIG. 1B is a cross-section through the plane A-A′ in FIG. 1A, and FIG. 1A is a cross-section through the plane B-B′ in FIG. 1B.

A number of elements are referred to in descriptions of FIGS. 1A-1B, 2, 3, and 5A-5I with reference numerals which correspond to different patterns illustrated in the figures, and legends are included at the bottoms of the pages including FIGS. 1A-1B, 2, 3, and 5A-5I, showing the correspondence between the reference numerals and patterns. The legend on the page including FIGS. 1A and 1B illustrates that FIGS. 1A and 1B use different patterns to show a support structure 102, a channel material 104, a dielectric material 106, a source or drain (S/D) region 108, a gate electrode 110, and a gate dielectric 112.

In general, implementations of the present disclosure may be formed or carried out on a support structure, e.g., the support structure 102 illustrated in FIG. 1. The support structure 102 may be, e.g., a substrate, a die, a wafer or a chip. For example, the support structure 102 may be the wafer 600 of FIG. 6A, discussed below, and may be, or be included in, a die, e.g., the singulated die 602 of FIG. 6B, discussed below. The support structure 102 extends along the x-y plane in the coordinate system shown in FIG. 1. In some embodiments, a support structure 102 may be used during a fabrication process and later removed. For example, a top side (e.g., front side) of the transistor 100 may be attached to a second support structure (e.g., a second one of the support structures 102, which may be referred to as a carrier structure), and the support structure 102 over which the transistor 100 is formed may be removed to expose a bottom side (e.g., back side) of the transistor 100.

In some embodiments, the support structure 102 may be a substrate that includes silicon and/or hafnium. More generally, the support structure 102 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the support structure 102 may be non-crystalline. In some embodiments, the support structure 102 may be a printed circuit board (PCB) substrate. Although a few examples of materials from which the support structure 102 may be formed are described here, any material that may serve as a foundation upon which a semiconductor device as described herein (e.g., a semiconductor device including one or more fin-shaped field effect transistors, nanoribbon transistors, or nanowire transistors) may be built falls within the spirit and scope of the present disclosure.

In FIGS. 1A and 1B, the transistor 100 is formed over the support structure 102. The transistor 100 includes a channel material 104 formed into four nanoribbons stacked on top of each other. In other examples, the transistor 100 may include more or fewer nanoribbons, e.g., one, two, three, five, six or more nanoribbons. The channel material 104 may be a semiconductor, and may include silicon or other semiconductor materials described herein.

The transistor 100 includes nanoribbons 120A, 120B, 120C, and 120D, referred to collectively as nanoribbons 120 or nanoribbon channels, or individually as a nanoribbon 120 or nanoribbon channel. Each nanoribbon 120 is at a different height in the z-direction in the orientation shown in FIGS. 1A and 1B, i.e., a different distance from the support structure 102, where the nanoribbon 120A is the greatest distance from the support structure 102, and the nanoribbon 120D is the smallest distance from the support structure 102. S/D regions 108A and 108B are formed at either end of the nanoribbon channels 120, as illustrated in FIG. 1A.

In general, to form nanoribbon channels such as the nanoribbon channels 120, alternating layers of the channel material 104 and a sacrificial material are deposited over the support structure 102. The sacrificial material is removed from the stack and replaced with other material, e.g., material for forming a gate stack 116, so the sacrificial material is not shown in FIG. 1. The channel material 104 and sacrificial materials include different materials. In one example, the channel material 104 is silicon, while the sacrificial material includes silicon and germanium. The sacrificial material may be chosen to have a similar crystal structure to the channel material 104, so that monocrystalline layers of the channel material 104 (or substantially monocrystalline layers, e.g., with a grain size of at least 5 nanometers, at least 20 nanometers, at least 50 nanometers, or at least 100 nanometers) and monocrystalline layers of the sacrificial material (or substantially monocrystalline layers) may be formed over each other. In different embodiments, the channel material 104 and/or the sacrificial material may be formed of any suitable single-crystal material, such as sapphire, quartz, silicon, a compound of silicon (e.g., silicon oxide), indium phosphide, germanium or a germanium alloy (e.g., silicon germanium), gallium, arsenic (e.g., an arsenide III compound, where arsenic III is in combination with another element such as boron, aluminum, gallium, or indium), or any group III-V material (i.e., materials from groups III and V of the periodic system of elements).

More generally, the channel material 104 may be composed of semiconductor material systems including, for example, N-type or P-type materials systems. In other embodiments, the channel material 104 may include a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. The channel material 104 may include one or more of cobalt oxide, copper oxide, ruthenium oxide, nickel oxide, niobium oxide, copper peroxide, indium telluride, molybdenite, molybdenum diselenide, tungsten diselenide, tungsten disulfide, molybdenum disulfide, N- or P-type amorphous or polycrystalline silicon, monocrystalline silicon, germanium, indium arsenide, indium gallium arsenide, indium selenide, indium antimonide, zinc antimonide, antimony selenide, silicon germanium, gallium nitride, aluminum gallium nitride, indium phosphite, black phosphorus, zinc sulfide, indium sulfide, gallium sulfide, each of which may possibly be doped with one or more of gallium, indium, aluminum, fluorine, boron, phosphorus, arsenic, nitrogen, tantalum, tungsten, and magnesium, etc.

In some embodiments, multiple channel materials may be included within an IC device. For example, an IC device may include both N-type metal oxide semiconductor (NMOS) transistors and P-type metal oxide semiconductor (PMOS) transistors, e.g., alternating rows of NMOS and PMOS transistors. NMOS and PMOS transistors can use different groups of channel material 104, e.g., silicon may be used to form an N-type semiconductor channel, while silicon germanium may be used to form a P-type semiconductor channel. In some embodiments, a single channel material 104 is used (e.g., silicon), and different portions (e.g., channel material to form different transistors) may include different dopants, e.g., N-type dopants for NMOS transistors and P-type dopants for PMOS transistors.

The S/D regions 108 may be formed from one or more layers of doped semiconductors, metals, metal alloys, or other materials. In some embodiments described herein, the S/D regions 108 may include a doped semiconductor, such as silicon or another semiconductor doped with an N-type dopant or a P-type dopant. In some embodiments, the S/D regions 108 may include multiple layers with different levels of conductivity, e.g., a doped semiconductor followed by a more highly doped semiconductor, or a semiconductor followed by metal.

A portion (e.g., a central portion) of each of the nanoribbon channels 120 is surrounded by a gate stack 116, which in this example, includes a gate electrode 110 and gate dielectric 112. Nanoribbon transistors often include a gate dielectric 112 that surrounds the nanoribbon channels 120, and a gate electrode 110 that surrounds the gate dielectric 112. While not specifically shown, in some embodiments, the gate dielectric 112 around each nanoribbon channel 120 includes multiple layers, e.g., an oxide layer and a high-k dielectric layer. The oxide layer may be grown directly on the nanoribbon channels 120, and the high-k dielectric may surround the oxide. The oxide may include oxygen in combination with the channel material 104. For example, if the nanoribbon channels are formed from silicon, the gate dielectric 112 may include a layer of silicon oxide. The high-k dielectric may be formed over the oxide. The gate electrode 110 surrounds the gate dielectric 112, e.g., the high-k dielectric (if included). In this example, the gate electrode 110 is above and below the nanoribbon stack, and between adjacent nanoribbon channels 120.

The gate electrode 110 includes a conductive material, such as a metal. The gate electrode 110 may include at least one P-type work function metal or N-type work function metal, depending on whether the transistor 100 is a PMOS transistor or an NMOS transistor. For a PMOS transistor, metals that may be used for the gate electrode 110 may include, but are not limited to, ruthenium, palladium, platinum, cobalt, nickel, and conductive metal oxides (e.g., ruthenium oxide). For an NMOS transistor, metals that may be used for the gate electrode 110 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode 110 may include a stack of two or more metal layers, where one or more metal layers are work function metal layers and at least one metal layer is a fill metal layer.

In various embodiments, the gate dielectric 112 may include one or more high-k dielectric materials and may include elements such as hafnium, silicon, oxygen, titanium, tantalum, lanthanum, aluminum, zirconium, barium, strontium, yttrium, lead, scandium, niobium, and zinc. Examples of high-k materials that may be used include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, the gate dielectric 112 may have a thickness between about 0.5 nanometers and 3 nanometers, including all values and ranges therein, e.g., between about 1 and 3 nanometers, or between about 1 and 2 nanometers.

Regions of the transistor 100 outside of the nanoribbons 120, gate stack 116, and S/D regions 108 are filled in with a dielectric material 106. The dielectric material 106 may include a low-k dielectric or a high-k dielectric. In some embodiments, the dielectric material 106 may include nitrogen. The dielectric material 106 may include silicon and nitrogen, e.g., silicon nitride. In some embodiments, the dielectric material 106 may include one or more dielectric materials that may include, but are not limited to, elements such as hafnium, silicon, oxygen, nitrogen, titanium, tantalum, lanthanum, aluminum, zirconium, barium, strontium, yttrium, lead, scandium, niobium, and zinc. Further examples of dielectric materials include, but are not limited to silicon oxide, silicon dioxide, silicon carbide, silicon nitride doped with carbon, silicon oxynitride, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate.

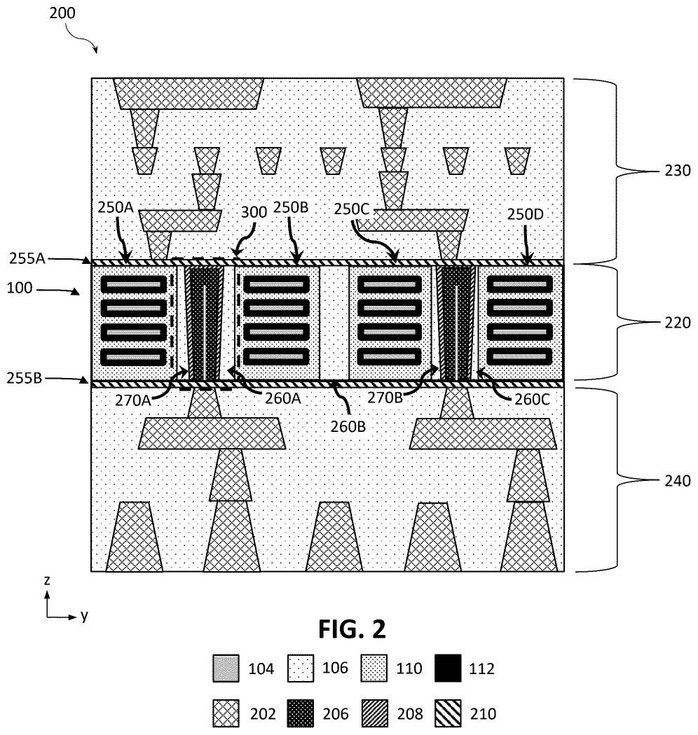

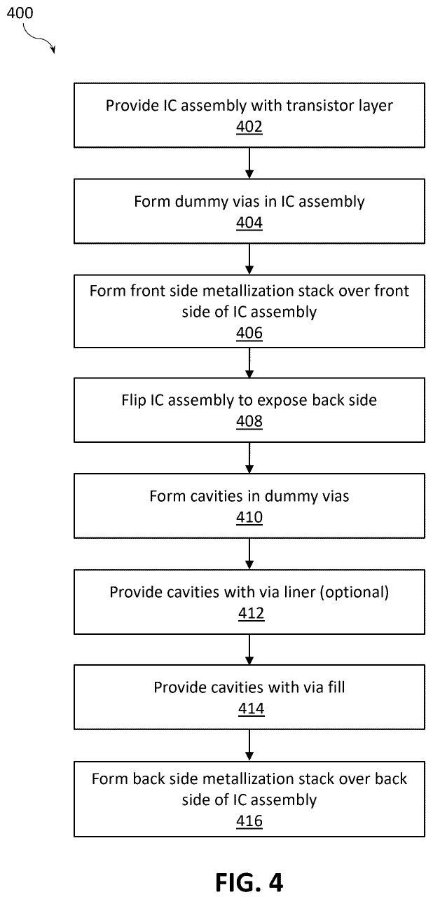

FIG. 1 illustrates a single nanoribbon transistor 100. In IC devices, many similar or identical transistors may be arranged within a device layer (such as a transistor layer, or a transistor assembly of a device layer). The dielectric material 106 and/or other materials may provide isolation between different transistors, or between other conductive materials in or near the device layer. As described with respect to FIGS. 2-5, IC devices can include vias that can extend through dielectric material 106 between different transistors, and methods of manufacturing such IC devices can involve processes described below (e.g., with reference to FIGS. 4 and 5), which can allow for one or more of the benefits or advantages described above to be realized.

FIG. 2 is a cross-section of an example IC device 200 including a transistor layer 220 between a front side metallization stack 230 (including one or more front side metallization layers) and a back side metallization stack 240 (including one or more back side metallization layers), according to some embodiments of the present disclosure. The transistor layer 220 may be an example of a device layer, and may include transistors 100, which may be the same as the transistors 100 described above with reference to FIG. 1. As shown, four transistors 100 (shown as first nanoribbon transistor 250A, second nanoribbon transistor 250B, third nanoribbon transistor 250C, and fourth nanoribbon transistor 250D) are included in the transistor layer 220, although in other embodiments, fewer or more transistors 100 may be provided in the transistor layer 220. The transistor layer 220 may include a via having a back side fill replacement, as described in more detail later in this disclosure.

The nanoribbon transistors 100 may be separated by dielectric material 106 (e.g., including dielectric material 106 present in a first zone 260A between first and second nanoribbon transistors 250A, 250B, in a second zone 260B between second and third nanoribbon transistors 250B, 250C, and in a third zone 260C between third and fourth nanoribbon transistors 250C, 250D). The dielectric material 106 may physically and/or electrically isolate individual transistors 100 or groups of transistors 100 from one another.

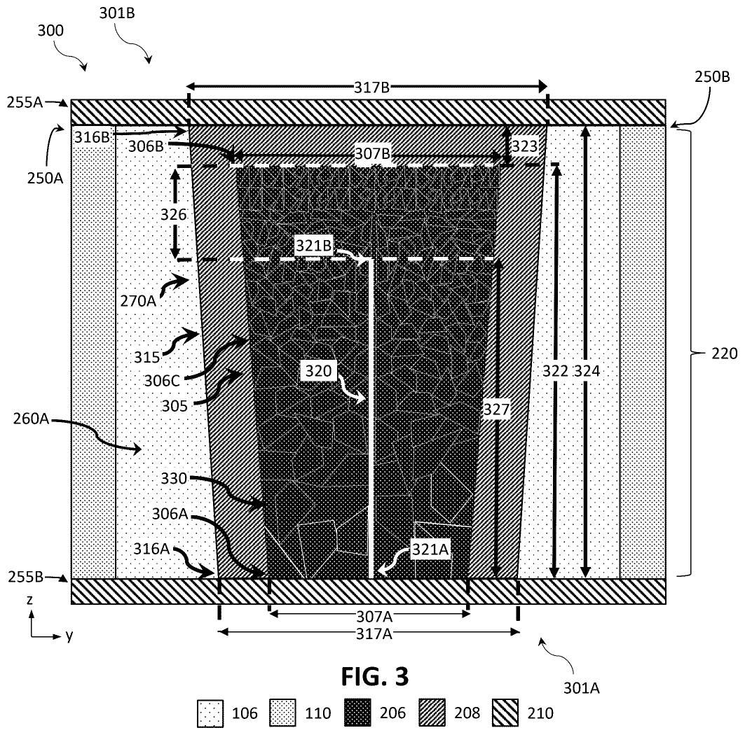

Conductive structures (e.g., including vias) may extend through the dielectric material 106 in the transistor layer 220 (e.g., with portions of the dielectric material 106 physically and/or electrically separating or isolating the conductive structures from transistors in the transistor layer 220). As shown in FIG. 2, a first conductive structure 270A is present within dielectric material 106 of the first zone 260A (e.g., between first and second nanoribbon transistors 250A, 250B, and particularly between gate structures (including the gate electrode 110 and the gate dielectric 112) of the first and second nanoribbon transistors 250A, 250B) and a second conductive structure 270B is present in dielectric material 106 of the third zone 260C (e.g., between third and fourth nanoribbon transistors 250C, 250D, and particularly between gate structures (including the gate electrode 110 and the gate dielectric 112) of the third and fourth nanoribbon transistors 250C, 250D). The conductive structures in the transistor layer 220 may, for example, connect components of the front side metallization stack 230 and components of the back side metallization stack 240 (e.g., for power, ground, and/or signal delivery or routing). The conductive structures are discussed further below with reference to FIG. 3, and with reference to a zoomed in area 300 outlined in dotted lines in FIG. 2.

In FIG. 2, the transistor layer 220 is adjacent to and between the front side metallization stack 230 and the back side metallization stack 240. The front and back side metallization stacks 230, 240 may each include one or more multiple metallization layers (also referred to as interconnect layers, as above), which may include lines and vias, the lines and vias including a conductive material 202. The conductive material 202 may include one or more metals or metal alloys, with materials such as copper, ruthenium, palladium, platinum, cobalt, nickel, hafnium, zirconium, titanium, tantalum, and aluminum, tantalum nitride, tungsten, doped silicon, doped germanium, or alloys and mixtures of any of these. In some embodiments, the conductive material 202 may include one or more electrically conductive alloys, oxides, or carbides of one or more metals. While FIG. 2 illustrates the same conductive material 202 for the lines and the vias, at each metallization layer, and for each type of interconnect (e.g., lines or vias), any suitable conductive material may be used. For example, in a given layer, the same conductive material may be used for both lines and vias, or different materials may be used for lines and vias. As another example, in different metallization layers, different materials may be used for the lines and/or vias, e.g., ruthenium may be included in the lines in one metallization layer, while copper is included in the lines of another metallization layer. In various embodiments, line or via structures may include multiple conductive materials, e.g., a first metal as a liner, and a second metal as a fill. The conductive material 202 may form conductive pathways to route power, ground, and/or signals to/from various components of the transistor layer 220, front side metallization stack 230, and/or back side metallization stack 240. The arrangement of the conductive material 202 in FIG. 2 is merely illustrative, and the conductive pathways in the IC device 200 may be connected to one another in any suitable manner.

The IC device 200 may also include first and second etch stop layers 255A, 255B. In FIG. 2, the etch stop layers 255A, 255B are shown on either side of the transistor layer 220 (e.g., the first etch stop layer 255A between the transistor layer 220 and the front side metallization stack 230, and the second etch stop layer 255B between the transistor layer 220 and the back side metallization stack 240). The etch stop layers 255A, 255B can help to prevent overetching of components of the IC device 200 during various manufacturing processes (e.g., during formation of lines and/or vias in the front side metallization stack 230 and/or back side metallization stack 240). The etch stop layers 255A, 255B may include an etch stop material 210, which may include any suitable material that can slow or stop undesired etching of components of the IC device 200. For example, the etch stop material 210 may include carbon and silicon, e.g., silicon carbide (SiC). Although only first and second etch stop layers 255A, 255B are shown, this is only to aid in understanding, and it should be understood that metallization layers in the front side metallization stack 230 and/or back side metallization stack 240 may include additional etch stop layers (e.g., adjacent to lines and/or vias in the front side or back side metallization stacks 230, 240) in order to avoid over etching of lines and/or vias.

The metal lines and vias in the front side and back side metallization stacks 230, 240 are in the dielectric material 106, which may include any of the materials described above with respect to the dielectric material 106. In some embodiments, different dielectric materials may be included in different ones of the metallization layers in the metallization stacks. In some embodiments, multiple dielectric materials may be present in a given metallization layer.

FIG. 3 is a zoomed in view of the area 300 shown in FIG. 2. In particular, FIG. 3 shows portions of the first and second nanoribbon transistors 250A, 250B (the portions including the gate electrode 110), portions of the first and second etch stop layers 255A, 255B, the first zone 260A (including the dielectric material 106), and the first conductive structure 270A.

The first conductive structure 270A has a first conductive structure end 301A and a second conductive structure end 301B opposite the first conductive structure end 301A. As shown in FIG. 2, the first conductive structure end 301A faces the back side metallization stack 240, and the second conductive structure end 301B faces the front side metallization stack 230. Referring back to FIG. 3, the first conductive structure 270A includes a via fill region 305 extending along a via fill region length 322 between a first via fill region end 306A adjacent to the first conductive structure end 301A and a second via fill region end 306B proximal to the second conductive structure end 301B (e.g., the second via fill region end 306B being more proximal to the second conductive structure end 301B than to the first conductive structure end 301A), the second via fill region end 306B opposite the first via fill region end 306A. A first via fill sidewall 306C extends between the first via fill region end 306A and the second via fill region end 306B. The first via fill region end 306A has a first via fill region width 307A, and the second via fill region end 306B has a second via fill region width 307B. The second via fill region width 307B may be greater than the first via fill region width 307A. For example, the first via fill region width 307A may be between 5 nm and 50 nm, or between 10 nm and 40 nm, or between 10 nm and 30 nm, or between 15 nm and 25 nm, or any ranges or sub-ranges therebetween. The second via fill region width 307B may be between 5 nm and 100 nm, or between 5 nm and 80 nm, or between 10 nm and 60 nm, or between 10 nm and 50 nm, or between 10 nm and 40 nm, or between 15 nm and 30 nm, or any ranges or sub-ranges therebetween. The first via fill region width 307A may be between 20% and 90% of the second via fill region width 307B, or between 30% and 80%, or between 40% and 70%, or between 50% and 60%, or any ranges or sub-ranges therebetween. The via fill region 305 may generally increase in width from the first via fill region end 306A to the second via fill region end 306B. The via fill region length 322 may be between 10 nm and 200 nm, or between 20 nm and 180 nm, or between 30 nm and 160 nm, or between 40 nm and 140 nm, or any ranges or sub-ranges therebetween.

The via fill region 305 may include a via fill material 206 that may be the same as or similar to the conductive material 202. The via fill material 206 may be provided to the via fill region 305 from a back side of the transistor layer 220, as a replacement fill material after removing a dummy via fill material from a space where the via fill material 206 is to be provided, as described further below with reference to FIGS. 4 and 5. As shown, the via fill material 206 may include a polycrystalline material (such as copper, tungsten, ruthenium, or another material, such as the conductive material 202) including crystal grains 330 having various shapes or geometries, orientations, and/or sizes. Crystal grains 330 at the first via fill region end 306A and crystal grains 330 at the second via fill region end 306B may have different sizes. For example, a crystal grain 330 at the first via fill region end 306A may have a first size, and a crystal grain 330 at the second via fill region end 306B may have a second size, where the first size is greater than the second size. A crystal grain 330 between the first via fill region end 306A and the second via fill region end 306B may have a third size between the first size and the second size. The crystal grain size may vary as a function of the particular polycrystalline material used. For example, if the polycrystalline material includes copper, the first size may be between 3 nm and 15 nm, or between 4 nm and 12 nm, or between 5 nm and 10 nm, or any ranges or sub-ranges therebetween, and the second size may be between 5 nm and 25 nm, or between 8 nm and 20 nm, or between 10 nm and 15 nm, or any ranges or sub-ranges therebetween. As another example, if the polycrystalline material includes tungsten, the first size may be between 0.5 nm and 4 nm, or between 1 nm and 3 nm, or between 1.5 nm and 2.5 nm, or any ranges or sub-ranges therebetween, and the second size may be between 1.5 nm and 7 nm, or between 2 nm and 6 nm, or between 3 nm and 5 nm, or any ranges or sub-ranges therebetween. As still another example, if the polycrystalline material includes ruthenium, the first size may be between 0.3 nm and 2 nm, or between 0.5 nm and 1.5 nm, or between 0.7 nm and 1 nm, or any ranges or sub-ranges therebetween, and the second size may be between 0.5nm and 4 nm, or between 0.8 nm and 3.5 nm, or between 1.2 nm and 2.8 nm, or between 1.5 nm and 2.5 nm, or any ranges or sub-ranges therebetween.

As another example, a first subset of the crystal grains 330 at or proximal to the first via fill region end 306A (e.g., for example, 10 crystal grains 330 selected randomly in a portion of the via fill region 305 extending from the first via fill region end 306A to a first distance 25% of the distance (e.g., along 25% of the via fill region length 322) to the second via fill region end 306B) may have a first average crystal grain size, a second subset of the crystal grains 330 at or proximal to the second via fill region end 306B (e.g., for example, 10 crystal grains 330 selected randomly in a portion of the via fill region 305 extending from the second via fill region end 306B to a second distance 25% of the distance (e.g., along 25% of the via fill region length 322) to the first via fill region end 306A) may have a second average crystal grain size, and the first average crystal grain size may be greater than the second average crystal grain size. A third subset of the crystal grains 330 between the first via fill region end 306A and the second via fill region end 306B (for example, 10 crystal grains 330 selected randomly in a portion of the via fill region 305 extending from the first distance to the second distance) may have a third average crystal grain size between the first average crystal grain size and the second average crystal grain size. The crystal grains 330 may generally decrease in size from the first via fill region end 306A to the second via fill region end 306B.

A seam 320 may be present in the via fill region 305. The seam 320 is a discontinuity in the via fill region 305 (i.e., in the via fill material 206). For example, the seam 320 may include an air gap between portions of the via fill material 206 in the via fill region 305, or a discontinuity in the structure of the via fill material 206 in the via fill region 305 (e.g., between crystal grains 330 of the via fill material 206). The seam 320 may extend along a seam length 327 between a first seam end 321A at or adjacent to the first via fill region end 306A to a second seam end 321B partway towards the second via fill region end 306B (e.g., between the first via fill region end 306A and the second via fill region end 306B). The seam length 327 may be shorter than the via fill region length 322 by a distance 326 between the second seam end 321B and the second via fill region end 306B. The distance 326 may be a portion of the second via fill region width 307B. For example, the distance 326 may be between 30% and 70% of the second via fill region width 307B, or between 40% and 60% of the second via fill region width 307B, or about 50% of the second via fill region width 307B. In FIG. 3, the seam 320 is shown as having a substantially rectangular cross-sectional profile, and the seam 320 is centered in the via fill region 305. However, the seam 320 is shown as such simply for ease of illustration, and part or all of the seam 320 could have a rough, jagged, or serrated profile (e.g., due to the seam being a discontinuity in the crystal grains 330, and due to variable shapes, geometries, orientations, and/or sizes of the crystal grains 330 bordering the seam 320). Additionally, part or all of the seam 320 may be off-center in the via fill region 305 (for example, closer to a portion of the first nanoribbon transistor 250A than a portion of the second nanoribbon transistor 250B, or closer to a portion of the second nanoribbon transistor 250B than a portion of the first nanoribbon transistor 250A). Furthermore, as described with reference to FIGS. 4 and 5 below, the seam 320 may be formed at least in part as a result of use of a conformal deposition process for filling the via fill region 305. In other embodiments, depending on the particular deposition process used to fill the via fill region 305 (for example, if a non-conformal deposition process such as electrolytic or electroless plating is used to fill the via fill region 305), little or no seam may be present.

The first conductive structure 270A may further include a liner 315. The liner 315 may be around a portion of the via fill region 305. As shown in FIG. 3, the liner 315 may surround or be around the via fill sidewall 306C and the second via fill region end 306B of the via fill region 305. The liner 315 may be between the via fill region 305 and the first and/or second nanoribbon transistors 250A, 250B (e.g., between the gate electrode 110 and the via fill region 305), or between the dielectric material 106 of the first zone 260A and the via fill region 305. A portion of the liner 315 (e.g., adjacent to the second via fill region end 306B) may be between the via fill region 305 and a portion of the front side metallization stack 230 (for example, dielectric material 106 or conductive material 202 in a front side metallization layer of the front side metallization stack 230).

The liner 315 has a liner length 324 between a first liner end 316A (e.g., at or adjacent to the first conductive structure end 301A) having a first liner width 317A and a second liner end 316B (e.g., at or adjacent to the second conductive structure end 301B) having a second liner width 317B. The second liner width 317B may be greater than the first liner width 317A. For example, the first liner width 317A may be between 5.2 nm and 60 nm or between 5.5 nm and 57 nm, or between 6 nm and 55 nm, or any ranges or sub-ranges therebetween, and the second liner width 317B may be between 5.2 nm and 110 nm, or between 5.5 nm and 107 nm, or between 6 nm and 105 nm, or any ranges or sub-ranges therebetween. The first liner width 317A may be between 20% and 90% of the second liner width 317B, or between 30% and 80%, or between 40% and 70%, or between 50% and 60%, or any ranges or sub-ranges therebetween. The liner length 324 may be between 10 nm and 210 nm, or between 20 nm and 190 nm, or between 30 nm and 170 nm, or between 40 nm and 150 nm, or any ranges or sub-ranges therebetween. The liner 315 also has a liner thickness 323 extending between the second liner end 316B and the second via fill region end 306B. The liner thickness 323 may be between 0.3 nm and 10 nm, or between 0.4 nm and 8 nm, or between 0.5 nm and 5 nm, or between 0.7 nm and 4 nm, or between 1 nm and 3 nm, or any ranges or sub-ranges therebetween. In some embodiments, the liner thickness 323 may be between 20% and 80% of the second via fill region width 307B, or between 30% and 70% of the second via fill region width 307B, or between 40% and 60% of the second via fill region width 307B. In some embodiments, the liner thickness 323 may be between 20% and 80% of the first via fill region width 307A, or between 30% and 70% of the first via fill region width 307A, or between 40% and 60% of the first via fill region width 307A.

The liner 315 may include a conductive liner material 208 that may allow for growth of the via fill material 206 in a cavity in the dielectric material 106 (the cavity serving as a site for formation of the first conductive structure 270A), as described in further detail below with reference to FIGS. 4 and 5. The conductive liner material 208 may include a metal, a metal alloy, a metal oxide, or a metal nitride. For example, the conductive liner material 208 may include a metal, such as titanium, tantalum, tungsten, or molybdenum, and/or an alloy of such metals, and may also include oxygen or nitrogen (e.g., titanium nitride, tantalum nitride, molybdenum nitride, or another nitride or an oxide).

FIG. 4 is a flow diagram of an example process 400 that may be used to manufacture an IC device having a through-device layer via having a back side fill replacement (such as the IC device 200), according to some embodiments of the present disclosure. FIGS. 5A-5I are side, cross-sectional views of various stages in the example process 400. Although the operations discussed below with reference to FIGS. 5A-5I (and others of the accompanying drawings representing manufacturing processes) are illustrated in a particular order, these operations may be performed in any suitable order. Further, additional operations which are not illustrated may also be performed without departing from the scope of the present disclosure. Also, various ones of the operations discussed herein with respect to FIGS. 5A-5I may be modified in accordance with the present disclosure to fabricate others of transistor assemblies disclosed herein.

At 402, an IC assembly (e.g., a portion of an IC device, which may also be an IC device) including a transistor layer (e.g., an example of a device layer as noted above) may be provided. FIG. 5A shows an IC assembly 500A including a transistor layer 520. As shown, the transistor layer 520 includes four nanoribbon transistors 550A, 550B, 550C, 550D (collectively nanoribbon transistors 550), which may be the same as or similar to the nanoribbon transistors 250A, 250B, 250C, 250D described above with reference to FIG. 2. The nanoribbon transistors 550 may be formed as described above with respect to the transistor 100 (e.g., over a support structure 102, which may be removed after formation of the nanoribbon transistors 550), and may include the same or similar materials as the transistor 100, including the channel material 104, the gate electrode 110, and the gate dielectric 112. Between the nanoribbon transistors 550A, 550B, 550C, 550D may be three zones 560A, 560B, 560C of dielectric material 106. The zones 560A, 560B, 560C (collectively zones 560) may be the same as or similar to the zones 260A, 260B, 260C described above with reference to FIG. 2, and may include the same dielectric material 106. The zones 560 may be formed between the nanoribbon transistors 550 using any suitable process. For example, the dielectric material 106 may be provided between the nanoribbon transistors 550 to form the zones 560 by a conformal deposition process (such as atomic layer deposition (ALD) or chemical vapor deposition (CVD)). Although four nanoribbon transistors 550A, 550B, 550C, 550D and three zones 560A, 560B, 560C are depicted in FIG. 5A, in other embodiments, greater or fewer numbers of nanoribbon transistors 550 or zones 560 may be provided in the IC assembly 500A.

At 404, dummy vias are formed in the IC assembly. FIG. 5B shows an IC assembly 500B, which may be the same as the IC assembly 500A, but after a process of forming dummy vias 502A, 502B in zones 560A, 560C. The dummy vias 502A, 502B may include a dummy via fill material 511. The dummy via fill material 511 may include a material with a lower coefficient of thermal expansion than copper or another via fill material (e.g., such as the via fill material 206 described above), with a low diffusivity (e.g., a lower diffusivity than copper or another via fill material (e.g., such as the via fill material 206) and/or may include a material that may have a higher etch selectivity than (e.g., be etched relatively more rapidly than) copper or another via fill material (such as the via fill material 206) (for example, using a wet etching process, or a dry etching process such as reactive ion etching, plasma etching, or another ion bombardment type etching process), with conventional etchants known in the art, such as fluorine-based etchants (including, for example, HF, CF₄, SF₆, CHF₃, etc.) or chlorine-based etchants (including, for example, HCl, Cl₂, BCl₃, CCl₄). For example, the dummy via fill material 511 may include a metal, a metal alloy, a metal oxide, or a non-metal material. In some embodiments, the dummy via fill material 511 may include silicon and oxygen (e.g., silica), silicon and nitrogen (e.g., silicon nitride), aluminum and oxygen (e.g., alumina), silicon and carbon (e.g., silicon carbide), or any other suitable material.

The dummy vias 502A, 502B may be formed by any suitable technique. For example, a photoresist material may be provided over portions of the transistor layer 520 by a suitable deposition technique such as, but not limited to, spin-coating, dip-coating, CVD, etc. Various materials that may be used as the photoresist material are well-known in the art, and are not described here in detail. Part of the photoresist material may be removed (e.g., patterning the layer of photoresist material) by a technique known in the art, such as photolithographic patterning, to expose the zones 560A, 560C. Part of the dielectric material 106 may be removed from the zones 560A, 560C to form dummy via openings. The dielectric material 106 may be removed by any suitable technique known in the art, such as by an etching process (e.g., a dry etch technique such as e.g., radio frequency (RF) reactive ion etch (RIE) or inductively coupled plasma (ICP) RIE, or a wet etch technique). Leftover photoresist material (e.g., outside of the etched region) may be removed by any suitable process, including by an ashing technique, in which the photoresist material is exposed to oxygen or fluorine, which may combine with the photoresist material to form an ash that can be easily removed. The dummy via fill material 511 may be provided in the dummy via openings in order to form the dummy vias 502A, 502B. The dummy via fill material 511 may be provided in the dummy via openings by any suitable process, such as a conformal deposition process (e.g., ALD, CVD, etc.) or a non-conformal deposition process (e.g., a non-conformal electroless or electrolytic plating process). In some embodiments, additional processes (such as processes of cleaning surfaces of the dummy vias 502A, 502B) or fewer processes may be used to complete the formation of the dummy vias 502A, 502B.

At 406, a front side metallization stack may be formed over a front side of the IC assembly. FIG. 5C shows an IC assembly 500C, which may be the same as the IC assembly 500B, but after a process of forming a front side metallization stack 530 over a front side of the IC assembly 500B (e.g., over the transistor layer 520). The front side metallization stack 530 may be the same as or similar to the front side metallization stack 230 described above with reference to FIG. 2, and the front side metallization stack 530 may similarly include conductive lines and vias including a conductive material 202. The front side metallization stack 530 may be formed using any suitable technique or techniques, such as dual damascene techniques, single damascene techniques, subtractive metallization patterning techniques, etc. The formation of the front side metallization stack 530 may include the formation of one or more etch stop layers (not shown; such as the etch stop layer 255A of FIG. 2) adjacent to components of the front side metallization stack 530 (e.g., adjacent to lines or vias). The etch stop layers may be deposited by any suitable process, such as by a plasma deposition process e.g., plasma enhanced chemical vapor deposition (PECVD). In CVD processes, gaseous precursors are introduced into a deposition chamber; the precursors react with an exposed surface, leading to the formation of a layer (or multiple layers or films, over the surface. In PECVD, a plasma environment is used to enhance the deposition process. For example, the plasma can cause dissociation of precursor molecules and the creation of large quantities of free radicals. Furthermore, the plasma can expose deposited etch stop material (e.g., the etch stop material 210 shown in FIG. 2) to energetic ion bombardment during deposition, which can lead to increases in the density of an etch stop layer and help remove contaminants, thus improving the layer's electrical and mechanical properties.

At 408, the IC assembly may be flipped to expose a back side of the IC assembly. FIG. 5D shows an IC assembly 500D, which may be the same as the IC assembly 500C, but after a process of flipping the IC assembly 500C to expose a back side of the IC assembly 500C (e.g., such that the front side metallization stack 530 is at the bottom of the IC assembly 500D and an exposed portion of the transistor layer 520 is at the top of the IC assembly 500D as shown in FIG. 5D). The flipping may be conducted by any suitable process. For example, after formation of the front side metallization stack 530, a carrier structure may be attached to the top or front of the front side metallization stack 530, and the IC assembly 500C may be flipped to the orientation of the IC assembly 500D shown in FIG. 5D.

At 410, cavities may be formed in the dummy vias. FIG. 5E shows an IC assembly 500E, which may be the same as the IC assembly 500D, but after a process of forming cavities 513 in the dummy vias 502A, 502B of the IC assembly 500D. Any suitable technique may be used for forming the cavities 513. For example, a selective etch chemistry may be used to etch the dummy via fill material 511 to form the cavities 513 while not etching or minimally etching other portions of the IC assembly 500D. Techniques for removing the dummy via fill material 511 to form the cavities 513 may also be similar to techniques used for removing part of the dielectric material 106 to form dummy via openings (as described above with reference to FIG. 5A), and may include processes of photolithography and etching, for example.

At 412, the cavities may optionally be provided with a via liner. FIG. 5F shows an IC assembly 500F, which may be the same as the IC assembly 500E, but after a process of providing via liners 512 in the cavities 513. The via liners 512 may be the same as or similar to the via liner 315 described above with reference to FIG. 3, and the via liners 512 may similarly comprise the conductive liner material 208. The via liners 512 may be provided by any suitable technique, including conformal deposition processes (e.g., ALD, CVD, etc.) similar to those described above.

At 414, the cavities may be provided with a via fill material. FIG. 5H shows an IC assembly 500H, which may be the same as the IC assembly 500F, but after a process of providing via fill material 206 (which may be the same as the via fill material 206 described above with reference to FIG. 3) to the cavities 513 (e.g., over the via liners 512), resulting in the formation of via fill regions 514 (which may be the same as the via fill region 305 described above with reference to FIG. 3). FIG. 5G shows an intermediate stage in the process of providing the via fill material 206 to the cavities 513 (leading to the formation of an intermediate IC assembly 500G). As shown in FIG. 5G and FIG. 5H, as the via fill material 206 is provided in the cavities 513, the cavities 513 become smaller, and in FIG. 5H, the cavities 513 are mostly filled, leaving behind seams (which may be the same as the seams 320 described above with reference to FIG. 3). The via fill material 206 may be provided by any suitable technique, including conformal deposition processes (e.g., ALD, CVD, etc.) similar to those described above. In some embodiments, a non-conformal deposition process (e.g., electrolytic metal plating) may be used to provide the via fill material 206 to the cavities 513. In some such embodiments, little or no seam may be formed.

At 416, a back side metallization stack may be formed over a back side of the IC assembly. FIG. 5I shows an IC assembly 5001, which may be the same as the IC assembly 500H, but after a process of forming a back side metallization stack 540 over the back side of the IC assembly 500H (e.g., over the top of the transistor layer 520 shown in FIG. 5H). The IC assembly 5001, if flipped such that the front side metallization stack 530 is at the top of the IC assembly 5001 (e.g., over the transistor layer 520) and such that the back side metallization stack 540 is at the bottom of the IC assembly 5001 (e.g., under the transistor layer 520), may be the same as or similar to the IC device 200 described above with reference to FIG. 2. The back side metallization stack 540 may be formed using any suitable technique or techniques, such as dual damascene techniques, single damascene techniques, subtractive metallization patterning techniques, etc. The formation of the back side metallization stack 540 may include the formation of one or more etch stop layers (not shown; such as the etch stop layer 255B of FIG. 2) adjacent to components of the back side metallization stack 540 (e.g., adjacent to lines or vias). The formation of the etch stop layers of the back side metallization stack 540 may be the same as or similar to the formation of the etch stop layers of the front side metallization stack 530 as described above.

The IC devices disclosed herein (having through-device layer vias having back side fill replacements) may be included in or associated with any suitable apparatus. FIGS. 6-9 illustrate various examples of apparatuses that may include one or more of the IC devices, which may have been fabricated using the processes disclosed herein.

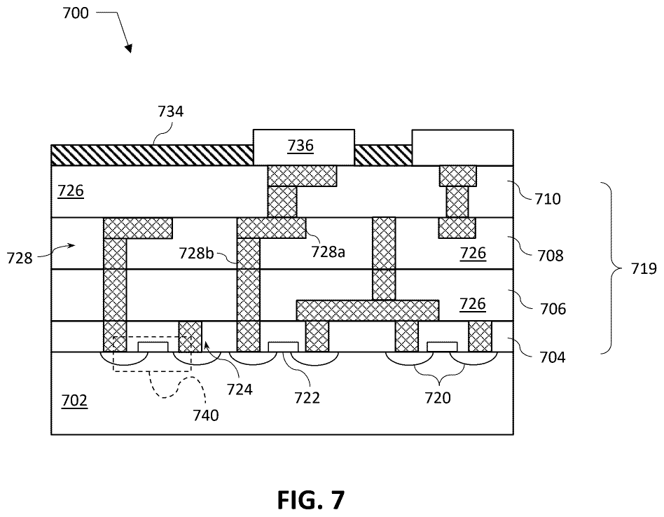

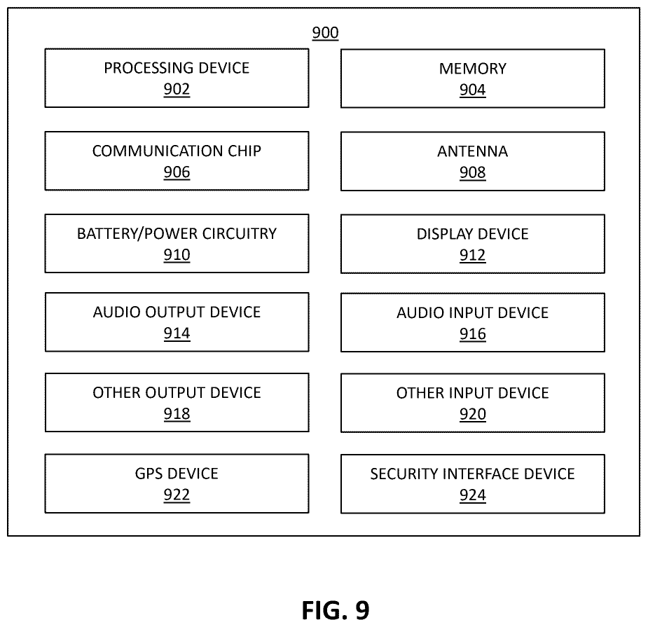

FIG. 6A and 6B are top views of a wafer and dies that include one or more IC devices in accordance with any of the embodiments disclosed herein. The wafer 600 may be composed of semiconductor material and may include one or more dies 602 having IC devices formed on a surface of the wafer 600. Each of the dies 602 may be a repeating unit of a semiconductor product that includes any suitable IC devices (e.g., IC devices as shown in or described with reference to any of FIGS. 1-5, or any further embodiments of the IC devices described herein). After the fabrication of the semiconductor product is complete (e.g., after manufacture of one or more IC devices as described herein, included in a particular electronic component, e.g., in a transistor device or in a memory device), the wafer 600 may undergo a singulation process in which each of the dies 602 is separated from one another to provide discrete “chips” of the semiconductor product. In particular, devices that include one or more of the IC devices as disclosed herein may take the form of the wafer 600 (e.g., not singulated) or the form of the die 602 (e.g., singulated). The die 602 may include one or more transistors (e.g., one or more of the transistors 100 of FIG. 1 discussed above or transistors 740 of FIG. 7, discussed below) and/or supporting circuitry to route electrical signals to the transistors, as well as any other IC components (e.g., one or more of the devices described herein). In some embodiments, the wafer 600 or the die 602 may include a memory device (e.g., a static random access memory (SRAM) device), a logic device (e.g., an AND, OR, NAND, or NOR gate), or any other suitable circuit element. Multiple ones of these devices may be combined on a single die 602. For example, a memory array formed by multiple memory devices may be formed on a same die 602 as a processing device (e.g., the processing device 902 of FIG. 9) or other logic that is configured to store information in the memory devices or execute instructions stored in the memory array.

FIG. 7 is a cross-sectional side view of an IC device 700 that may be or include one or more IC devices in accordance with any of the embodiments disclosed herein (e.g., embodiments described above with reference to FIGS. 1-5), at any suitable location in the IC device 700. The IC device 700 may be formed on a substrate 702 (e.g., the wafer 600 of FIG. 6A) and may be included in a die (e.g., the die 602 of FIG. 6B). The substrate 702 may be any substrate as described herein. The substrate 702 may be part of a singulated die (e.g., the dies 602 of FIG. 6B) or a wafer (e.g., the wafer 600 of FIG. 6A).

The IC device 700 may include a device layer 704 (which may be the same as or similar to the transistor layer 220 of FIG. 2) disposed on the substrate 702. In some embodiments, more than one device layer 704 may be included. The device layer 704 may include features of one or more transistors 740 (e.g., metal oxide semiconductor field effect transistors (MOSFETs)) formed on the substrate 702. The device layer 704 may include, for example, one or more source and/or drain (S/D) regions 720, a gate 722 to control current flow in the transistors 740 between the S/D regions 720, and one or more S/D contacts 724 to route electrical signals to/from the S/D regions 720. The transistors 740 may include additional features not depicted for the sake of clarity, such as device isolation regions, gate contacts, and the like. The transistors 740 are not limited to the type and configuration depicted in FIG. 7 and may include a wide variety of other types and configurations such as, for example, planar transistors, non-planar transistors, or a combination of both. Non-planar transistors may include fin-type field effect transistors (FinFETs), such as double-gate transistors or tri-gate transistors, and wrap-around or all-around gate transistors, such as nanoribbon and nanowire transistors.

Each transistor 740 may include a gate 722 formed of at least two layers, a gate electrode layer and a gate dielectric layer. The gate electrode layer may be formed on the gate interconnect support layer and may consist of at least one P-type workfunction metal or N-type workfunction metal, depending on whether the transistor is to be a PMOS or an NMOS transistor, respectively. In some implementations, the gate electrode layer may consist of a stack of two or more metal layers, where one or more metal layers are workfunction metal layers and at least one metal layer is a fill metal layer. Further metal layers may be included for other purposes, such as a barrier layer or/and an adhesion layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer may enable the formation of a PMOS gate electrode with a workfunction that is between about 4.9 electron Volts (eV) and about 5.2 eV, for example. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, aluminum carbide, tungsten, tungsten carbide. An N-type metal layer may enable the formation of an NMOS gate electrode with a workfunction that is between about 3.9 eV and about 4.2 eV, for example.

In some embodiments, when viewed as a cross-section of the transistor 740 along the source-channel-drain direction, the gate electrode may be formed as a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may be implemented as a combination of U-shaped structures and planar, non-U-shaped structures. For example, the gate electrode may be implemented as one or more U-shaped metal layers formed atop one or more planar, non-U-shaped layers. In some embodiments, the gate electrode may consist of a V-shaped structure (e.g., when a fin of a FinFET transistor does not have a “flat” upper surface, but instead has a rounded peak).

Generally, the gate dielectric layer of a transistor 740 may include one layer or a stack of layers, and the one or more layers may include silicon oxide, silicon dioxide, and/or a high-k dielectric material. The high-k dielectric material included in the gate dielectric layer of the transistor 740 may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The S/D regions 720 may be formed within the substrate 702 adjacent to the gate 722 of each transistor 740, using any suitable processes known in the art. For example, the S/D regions 720 may be formed using either an implantation/diffusion process or a deposition process. In the former process, dopants such as boron, aluminum, antimony, phosphorous, or arsenic may be ion-implanted into the substrate 702 to form the S/D regions 720. An annealing process that activates the dopants and causes them to diffuse farther into the substrate 702 may follow the ion implantation process. In the latter process, an epitaxial deposition process may provide material that is used to fabricate the S/D regions 720. In some implementations, the S/D regions 720 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 720 may be formed using one or more alternate semiconductor materials such as germanium or a group III-V material or alloy. In further embodiments, one or more layers of metal and/or metal alloys may be used to form the S/D regions 720. In some embodiments, an etch process may be performed before the epitaxial deposition to create recesses in the substrate 702 in which the material for the S/D regions 720 is deposited.

Electrical signals, such as power and/or input/output (I/O) signals, may be routed to and/or from the transistors 740 of the device layer 704 through one or more interconnect layers disposed on the device layer 704 (illustrated in FIG. 7 as interconnect layers 706-710). For example, electrically conductive features of the device layer 704 (e.g., the gate 722 and the S/D contacts 724) may be electrically coupled with the interconnect structures 728 of the interconnect layers 706-710. The one or more interconnect layers 706-709 may form an ILD stack 719 of the IC device 70.

The interconnect structures 728 may be arranged within the interconnect layers 706-710 to route electrical signals according to a wide variety of designs (in particular, the arrangement is not limited to the particular configuration of interconnect structures 728 depicted in FIG. 7). Although a particular number of interconnect layers 706-710 is depicted in FIG. 7, embodiments of the present disclosure include IC devices having more or fewer interconnect layers than depicted.

In some embodiments, the interconnect structures 728 may include lines 728a and/or vias 728b filled with an electrically conductive material such as a metal. The lines 728a may be arranged to route electrical signals in a direction of a plane that is substantially parallel with a surface of the substrate 702 upon which the device layer 704 is formed. For example, the lines 728a may route electrical signals in a direction in and out of the page from the perspective of FIG. 7. The vias 728b may be arranged to route electrical signals in a direction of a plane that is substantially perpendicular to the surface of the substrate 702 upon which the device layer 704 is formed. In some embodiments, the vias 728b may electrically couple lines 728a of different interconnect layers 706-710 together.

The interconnect layers 706-710 may include a dielectric material 726 disposed between the interconnect structures 728, as shown in FIG. 7. The dielectric material 726 may take the form of any of the embodiments of the dielectric material provided between the interconnects of the IC structures disclosed herein.

In some embodiments, the dielectric material 726 disposed between the interconnect structures 728 in different ones of the interconnect layers 706-710 may have different compositions. In other embodiments, the composition of the dielectric material 726 between different interconnect layers 706-710 may be the same.

A first interconnect layer 706 (referred to as metal 1 or “M1”) may be formed directly on the device layer 704. In some embodiments, the first interconnect layer 706 may include lines 728a and/or vias 728b, as shown. The lines 728a of the first interconnect layer 706 may be coupled with contacts (e.g., the S/D contacts 724) of the device layer 704.

A second interconnect layer 708 (referred to as metal 2 or “M2”) may be formed directly on the first interconnect layer 706. In some embodiments, the second interconnect layer 708 may include vias 728b to couple the lines 728a of the second interconnect layer 708 with the lines 728a of the first interconnect layer 706. Although the lines 728a and the vias 728b are structurally delineated with a line within each interconnect layer (e.g., within the second interconnect layer 708) for the sake of clarity, the lines 728a and the vias 728b may be structurally and/or materially contiguous (e.g., simultaneously filled during a dual damascene process) in some embodiments.

A third interconnect layer 710 (referred to as metal 3 or “M3”) (and additional interconnect layers, as desired) may be formed in succession on the second interconnect layer 708 according to similar techniques and configurations described in connection with the second interconnect layer 708 or the first interconnect layer 706.

The IC device 700 may include a solder resist material 734 (e.g., polyimide or similar material) and one or more bond pads 736 formed on the interconnect layers 706-710. The bond pads 736 may be electrically coupled with the interconnect structures 728 and configured to route the electrical signals of the transistor(s) 740 to other external devices. For example, solder bonds may be formed on the one or more bond pads 736 to mechanically and/or electrically couple a chip including the IC device 700 with another component (e.g., a circuit board). The IC device 700 may have other alternative configurations to route the electrical signals from the interconnect layers 706-710 than depicted in other embodiments. For example, the bond pads 736 may be replaced by or may further include other analogous features (e.g., posts) that route the electrical signals to external components.

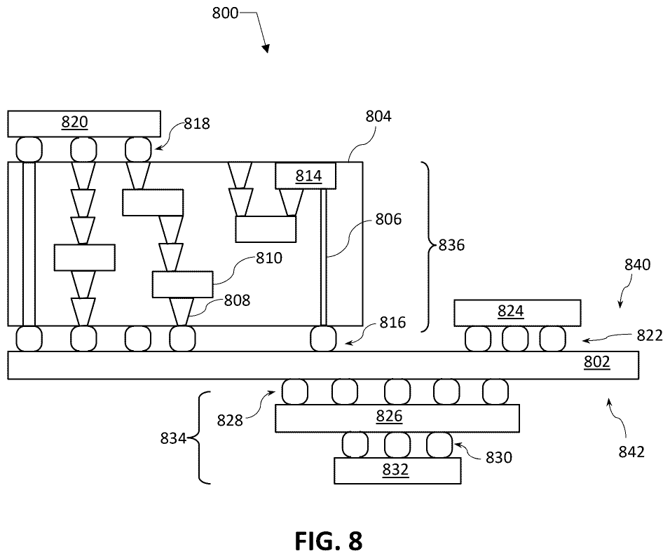

FIG. 8 is a cross-sectional side view of an IC device assembly 800 that may include or be associated with (e.g., being electrically connected to) one or more IC devices having through-device layer vias having back side fill replacements, in accordance with any of the embodiments disclosed herein. The IC device assembly 800 includes a number of components disposed on a circuit board 802 (which may be, e.g., a motherboard). The IC device assembly 800 includes components disposed on a first face 840 of the circuit board 802 and an opposing second face 842 of the circuit board 802; generally, components may be disposed on one or both faces 840 and 842. Any suitable ones of the components of the IC device assembly 800 may include one or more through-device layer vias having back side fill replacements disclosed herein.

In some embodiments, the circuit board 802 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 802. In other embodiments, the circuit board 802 may be a non-PCB substrate.

The IC device assembly 800 illustrated in FIG. 8 includes a package-on-interposer structure 836 coupled to the first face 840 of the circuit board 802 by coupling components 816. The coupling components 816 may electrically and mechanically couple the package-on-interposer structure 836 to the circuit board 802 and may include solder balls (as shown in FIG. 8), male and female portions of a socket, an adhesive, an underfill material, and/or any other suitable electrical and/or mechanical coupling structure.

The package-on-interposer structure 836 may include an IC package 820 coupled to an interposer 804 by coupling components 818. The coupling components 818 may take any suitable form for the application, such as the forms discussed above with reference to the coupling components 816. Although a single IC package 820 is shown in FIG. 8, multiple IC packages may be coupled to the interposer 804; indeed, additional interposers may be coupled to the interposer 804. The interposer 804 may provide an intervening substrate used to bridge the circuit board 802 and the IC package 820. The IC package 820 may be or include, for example, a die (the die 602 of FIG. 6B), an IC device (e.g., the IC device 200 of FIG. 2, the IC device 700 of FIG. 7, etc.), or any other suitable component. Generally, the interposer 804 may spread a connection to a wider pitch or reroute a connection to a different connection. For example, the interposer 804 may couple the IC package 820 (e.g., a die, such as the die 602 of FIG. 6B) to a ball grid array (BGA) of the coupling components 816 for coupling to the circuit board 802. In the embodiment illustrated in FIG. 8, the IC package 820 and the circuit board 802 are attached to opposing sides of the interposer 804; in other embodiments, the IC package 820 and the circuit board 802 may be attached to a same side of the interposer 804. In some embodiments, three or more components may be interconnected by way of the interposer 804.

The interposer 804 may be formed of an epoxy resin, a fiberglass-reinforced epoxy resin, a ceramic material, or a polymer material such as polyimide. In some implementations, the interposer 804 may be formed of alternate rigid or flexible materials that may include the same materials described above for use in a semiconductor substrate, such as silicon, germanium, and other group III-V and group IV materials. The interposer 804 may include metal interconnects 808 and vias 810 (including but not limited to vias 806, which may be through silicon vias (TSVs)). The interposer 804 may further include embedded devices 814, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on the interposer 804. The package-on-interposer structure 836 may take the form of any of the package-on-interposer structures known in the art.

The IC device assembly 800 may include an IC package 824 coupled to the first face 840 of the circuit board 802 by coupling components 822. The coupling components 822 may take the form of any of the embodiments discussed above with reference to the coupling components 816, and the IC package 824 may take the form of any of the embodiments discussed above with reference to the IC package 820.

The IC device assembly 800 illustrated in FIG. 8 includes a package-on-package structure 834 coupled to the second face 842 of the circuit board 802 by coupling components 828. The package-on-package structure 834 may include an IC package 826 and an IC package 832 coupled together by coupling components 830 such that the IC package 826 is disposed between the circuit board 802 and the IC package 832. The coupling components 828 and 830 may take the form of any of the embodiments of the coupling components 816 discussed above, and the IC packages 826 and 832 may take the form of any of the embodiments of the IC package 820 discussed above. The package-on-package structure 834 may be configured in accordance with any of the package-on-package structures known in the art.

FIG. 9 is a block diagram of an example computing device 900 that may include one or more IC devices having through-device layer vias having back side fill replacements, in accordance with any of the embodiments disclosed herein. For example, any suitable ones of the components of the computing device 900 may include a die (e.g., the die 602 of FIG. 6B) having one or more IC devices having through-device layer vias having back side fill replacements. Any one or more of the components of the computing device 900 may include, or be included in, an IC device (e.g., the IC device 200, or the IC device 700 of FIG. 7). Any one or more of the components of the computing device 900 may include, or be included in, an IC device assembly (e.g., the IC device assembly 800 of FIG. 8).

A number of components are illustrated in FIG. 9 as included in the computing device 900, but any one or more of these components may be omitted or duplicated, as suitable for the application. In some embodiments, some or all of the components included in the computing device 900 may be attached to one or more motherboards. In some embodiments, some or all of these components are fabricated onto a single system-on-a-chip (SoC) die.

Additionally, in various embodiments, the computing device 900 may not include one or more of the components illustrated in FIG. 9, but the computing device 900 may include interface circuitry for coupling to the one or more components. For example, the computing device 900 may not include a display device 912, but may include display device interface circuitry (e.g., a connector and driver circuitry) to which a display device 912 may be coupled. In another set of examples, the computing device 900 may not include an audio input device 916 or an audio output device 914, but may include audio input or output device interface circuitry (e.g., connectors and supporting circuitry) to which an audio input device 916 or audio output device 914 may be coupled.

The computing device 900 may include a processing device 902 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 902 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 900 may include a memory 904, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 904 may include memory that shares a die with the processing device 902. This memory may be used as cache memory and may include embedded dynamic random access memory (eDRAM) or spin transfer torque magnetic random access memory (STT-MRAM).

In some embodiments, the computing device 900 may include a communication chip 906 (e.g., one or more communication chips). For example, the communication chip 906 may be configured for managing wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 906 may implement any of a number of wireless standards or protocols, including but not limited to Institute for Electrical and Electronic Engineers (IEEE) standards including Wi-Fi (IEEE 1402.11 family), IEEE 1402.18 standards (e.g., IEEE 1402.18-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.18 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.18 standards. The communication chip 906 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 906 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 906 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 906 may operate in accordance with other wireless protocols in other embodiments. The computing device 900 may include an antenna 908 to facilitate wireless communications and/or to receive other wireless communications (such as AM or FM radio transmissions).

In some embodiments, the communication chip 906 may manage wired communications, such as electrical, optical, or any other suitable communication protocols (e.g., the Ethernet). As noted above, the communication chip 906 may include multiple communication chips. For instance, a first communication chip 906 may be dedicated to shorter-range wireless communications such as Wi-Fi or Bluetooth, and a second communication chip 906 may be dedicated to longer-range wireless communications such as global positioning system (GPS), EDGE, GPRS, CDMA, WiMAX, LTE, EV-DO, or others. In some embodiments, a first communication chip 906 may be dedicated to wireless communications, and a second communication chip 906 may be dedicated to wired communications.

The computing device 900 may include a battery/power circuitry 910. The battery/power circuitry 910 may include one or more energy storage devices (e.g., batteries or capacitors) and/or circuitry for coupling components of the computing device 900 to an energy source separate from the computing device 900 (e.g., AC line power).

The computing device 900 may include a display device 912 (or corresponding interface circuitry, as discussed above). The display device 912 may include any visual indicators, such as a heads-up display, a computer monitor, a projector, a touchscreen display, a liquid crystal display (LCD), a light-emitting diode display, or a flat panel display, for example.

The computing device 900 may include an audio output device 914 (or corresponding interface circuitry, as discussed above). The audio output device 914 may include any device that generates an audible indicator, such as speakers, headsets, or earbuds, for example.

The computing device 900 may include an audio input device 916 (or corresponding interface circuitry, as discussed above). The audio input device 916 may include any device that generates a signal representative of a sound, such as microphones, microphone arrays, or digital instruments (e.g., instruments having a musical instrument digital interface (MIDI) output).

The computing device 900 may include an other output device 918 (or corresponding interface circuitry, as discussed above). Examples of the other output device 918 may include an audio codec, a video codec, a printer, a wired or wireless transmitter for providing information to other devices, or an additional storage device.

The computing device 900 may include an other input device 920 (or corresponding interface circuitry, as discussed above). Examples of the other input device 920 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 900 may include a GPS device 922 (or corresponding interface circuitry, as discussed above). The GPS device 922 may be in communication with a satellite-based system and may receive a location of the computing device 900, as known in the art.

The computing device 900 may include a security interface device 924. The security interface device 924 may include any device that provides security features for the computing device 900 or for any individual components therein (e.g., for the processing device 902 or for the memory 904). Examples of security features may include authorization, access to digital certificates, access to items in keychains, etc. Examples of the security interface device 924 may include a software firewall, a hardware firewall, an antivirus, a content filtering device, or an intrusion detection device.

The computing device 900 may have any desired form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 900 may be any other electronic device that processes data.

The following paragraphs provide various examples of the embodiments disclosed herein.

Example 1 provides a device (e.g., an integrated circuit device or an IC device) including a first metallization layer; a second metallization layer; and a transistor layer between the first metallization layer and the second metallization layer, the transistor layer including a first gate structure; a second gate structure; and a conductive structure between the first gate structure and the second gate structure, where the conductive structure has: a first end having a first width, the first end closer to the first metallization layer than the second metallization layer; a second end having a second width, the second end closer to the second metallization layer than the first metallization layer, the second width greater than the first width, and a seam extending from the first end partway towards the second end.

Example 2 provides the device of example 1, where the conductive structure increases in width from the first end to the second end.

Example 3 provides the device of examples 1 or 2, where the first width is between 20% and 90% of the second width.

Example 4 provides the device of any one of examples 1-3, where the seam has a first seam end proximal to the first end of the conductive structure and a second seam end proximal to the second end of the conductive structure, and a distance between the second seam end and the second end of the conductive structure is between 30% and 70% of the second width.

Example 5 provides the device of any one of examples 1-4, where the conductive structure includes a polycrystalline material having a first crystal grain size at the first end and a second crystal grain size at the second end, the second crystal grain size smaller than the first crystal grain size.

Example 6 provides the device of example 5, where the first crystal grain size is between 0.5 nm and 10 nm.

Example 7 provides the device of example 5 or 6, where the second crystal grain size is between 2.5 nm and 25 nm.

Example 8 provides the device of any one of examples 1-7, where the conductive structure includes a liner over the second end of the conductive structure.

Example 9 provides the device of example 8, where the conductive structure includes a sidewall extending from the first end to the second end, and the liner is over the sidewall.

Example 10 provides the device of examples 8 or 9, where the liner has a thickness of between 0.5 nm and 5 nm.

Example 11 provides the device of any one of examples 8-10, where the liner includes at least one of titanium, tungsten, ruthenium, molybdenum, and tantalum.

Example 12 provides the device of any one of examples 1-11, further including a dielectric material between the conductive structure and the first gate structure.

Example 13 provides an assembly including a packaging component and a die coupled to the packaging component, the die including a first semiconductor device; a second semiconductor device; and a via between the first semiconductor device and the second semiconductor device, the via having a first end and a second end opposite the first end, and the second end wider than the first end, where the via includes a polycrystalline material having a crystal grain size that is smaller at the second end than at the first end.

Example 14 provides the assembly of example 13, where the first semiconductor device and the second semiconductor device are between a first metallization layer and a second metallization layer.

Example 15 provides the assembly of examples 13 or 14, where the crystal grain size decreases from the first end to the second end.

Example 16 provides the assembly of any one of examples 13-15, where the crystal grain size is between 0.5 nm and 10 nm at the first end.

Example 17 provides the assembly of any one of examples 13-16, where the crystal grain size is between 2.5 nm and 25 nm at the second end.

Example 18 provides the assembly of any one of examples 13-17, where the via includes a liner, the liner surrounding the second end of the via and a sidewall of the via, the sidewall extending from the first end of the via to the second end of the via.

Example 19 provides the assembly of any one of examples 13-17, where the via includes a liner, the liner between the via and the first semiconductor device.

Example 20 provides the assembly of examples 18 or 19, further including a dielectric material between the liner and the first semiconductor device.

Example 21 provides the assembly of any one of examples 18-20, where the liner has a thickness of between 0.5 nm and 5 nm.

Example 22 provides the assembly of any one of examples 19-21, where the liner includes at least one of titanium, tungsten, ruthenium, molybdenum, and tantalum.

Example 23 provides a device including a first transistor; a second transistor; a via between the first transistor and a second transistor, the via including a first end, a second end having a greater width than the first end, and a sidewall between the first end and the second end; and a conductive liner over the sidewall and the second end of the via.

Example 24 provides the device of example 23, where the conductive liner has a thickness of between 0.5 nm and 5 nm.

Example 25 provides the device of examples 23 or 24, where the conductive liner includes a metal.

Example 26 provides the device of any one of examples 23-25 further including a dielectric material between the via and the first transistor.

Example 27 provides the device of any one of examples 23-26 where the via is physically isolated from at least one of the first transistor and the second transistor.

Example 28 provides the device of any one of examples 23-27, where the via is between a first gate structure of the first transistor and a second gate structure of the second transistor.

Example 29 provides the device of example 28, where the via is electrically isolated from at least one of the first gate structure and the second gate structure.

1. A device comprising:
a first metallization layer;
a second metallization layer; and
a transistor layer between the first metallization layer and the second metallization layer, the transistor layer comprising a first gate structure, a second gate structure, and a conductive structure between the first gate structure and the second gate structure, wherein the conductive structure has:
a first end having a first width, the first end closer to the first metallization layer than the second metallization layer;
a second end having a second width, the second end closer to the second metallization layer than the first metallization layer, the second width greater than the first width, and
a seam extending from the first end and partway towards the second end.

2. The device of claim 1, wherein the conductive structure increases in width from the first end to the second end.

3. The device of claim 1, wherein the first width is between 20% and 90% of the second width.

4. The device of claim 1, wherein the seam has a first seam end proximal to the first end of the conductive structure and a second seam end proximal to the second end of the conductive structure, and a distance between the second seam end and the second end of the conductive structure is between 30% and 70% of the second width.

5. The device of claim 1, wherein the conductive structure includes a polycrystalline material having a first crystal grain size at the first end and a second crystal grain size at the second end, the second crystal grain size smaller than the first crystal grain size.

6. The device of claim 1, wherein the conductive structure includes a liner over the second end of the conductive structure.

7. The device of claim 6, wherein the conductive structure includes a sidewall extending from the first end to the second end, and the liner is over the sidewall.

8. The device of claim 6, wherein the liner includes at least one of titanium, tungsten, ruthenium, molybdenum, and tantalum.

9. The device of claim 1, further comprising a dielectric material between the conductive structure and the first gate structure.

10. An assembly comprising:
a packaging component; and
a die coupled to the packaging component, the die comprising:
a first semiconductor device;
a second semiconductor device; and
a via between the first semiconductor device and the second semiconductor device, the via having a first end and a second end opposite the first end, and the second end wider than the first end, wherein the via includes a polycrystalline material having a crystal grain size that is smaller at the second end than at the first end.

11. The assembly of claim 10, wherein the first semiconductor device and the second semiconductor device are between a first metallization layer and a second metallization layer.

12. The assembly of claim 10, wherein the crystal grain size decreases from the first end to the second end.

13. The assembly of claim 10, wherein the via includes a liner, the liner surrounding the second end of the via and a sidewall of the via, the sidewall extending from the first end of the via to the second end of the via.

14. The assembly of claim 10, wherein the via includes a liner, the liner between the via and the first semiconductor device.

15. The assembly of claim 14, further comprising a dielectric material between the liner and the first semiconductor device.

16. The assembly of claim 14, wherein the liner includes at least one of titanium, tungsten, ruthenium, molybdenum, and tantalum.

17. A device comprising:
a first transistor;
a second transistor;
a via between the first transistor and a second transistor, the via including a first end, a second end having a greater width than the first end, and a sidewall between the first end and the second end; and
a conductive liner over the sidewall and the second end of the via.

18. The device of claim 17, wherein the conductive liner has a thickness of between 0.5 nm and 5 nm.

19. The device of claim 17 wherein the via is physically isolated from at least one of the first transistor and the second transistor.

20. The device of any claim 17, wherein the via is between a first gate structure of the first transistor and a second gate structure of the second transistor.
